(19) United States
(12) Patent Application Publication
(10) Pub. No.: US 2004/0238268 A1
(43) Pub. Date: Dec. 2, 2004

(54) Sound reproducing apparatus and method for optimizing same

(76) Inventors: Thomas J. Danley, Highland Park, IL (US); Bradford J. Skuran, Glenview, IL (US)

Correspondence Address: FITCH, EVEN, TABIN & FLANNERY, Suite 1600, 120 South LaSalle Street, Chicago, IL, 60603-3406, US

(21) Appl. No.: 10/800,150

(22) Filed: Mar. 13, 2004

Related U.S. Application Data
(60) Provisional application No. 60/455,109, filed on Mar. 13, 2003.

(51) Int. Cl. H05K 5/00; G10K 11/00; A47B 81/06

(52) U.S. Cl. 181/199; 181/155

(57) ABSTRACT

A sound reproducing apparatus in accordance with the invention includes a body, such as a housing, a driver for reproducing a desired sound and an acoustic passageway through which the reproduced sound is output. The acoustic passageway having an internal portion, such as a horn, located within the body of the apparatus and an external portion defined by at least one of the exterior surfaces of the body and/or a boundary of the environment within which the apparatus is placed. In one form, the external portion of the acoustic path is defined by an exterior surface or surfaces of the body and a wall, floor or ceiling. In another form, the external portion of the acoustic path is defined by an exterior surface or surfaces of the body and another acoustic reproducing apparatus. In yet another form, the external portion of the acoustic path is defined by an exterior surface or surfaces of the body, by a wall, floor or ceiling, and by another acoustic reproducing apparatus.

### BACKGROUND OF THE INVENTION

This invention relates generally to sound reproduction and more particularly concerns apparatus and methods for providing more powerful and efficient loudspeaker horns at low frequencies.

The audio industry provides a variety of sound reproduction apparatus, such as loudspeakers, which are capable of generating desired audio outputs. Typically, the performance and expense of these apparatus are limited by their size. For example, the low frequency limit of a horn is set by the horn expansion rate and the size of the horn itself can be no shorter than about one-quarter the wavelength at the lowest frequency the apparatus is to operate if the apparatus is to function properly.

The expansion rate pertains to how fast the air path of the horn expands. This rate governs the frequency the apparatus can go down to and still continue to operate properly. For example, to go down to 30 Hz (cycles/second) requires an expansion rate where the area of the horn opening doubles about every two feet as it approaches the mouth. If you only want to go down to 60 Hz (an octave above) than the area of the horn opening need only double about every twelve two feet. Thus, how fast it expands has a direct correlation to how low (frequency wise) the horn will operate. A problem associated with this is that as you go down in frequency, the physical size of the apparatus becomes increasingly large. Eventually, the size of the horn becomes so large that it makes the apparatus impractical or unfeasible for many, if not all, applications. For example, in order to make a horn that goes down an octave lower, it would require the minimum horn length to be twice as long and require the mouth of the horn to have twice the circumference. At 30 Hz and in full space, the mouth of the apparatus would need to be about 37.77 feet in circumference or about twelve feet in diameter and a minimum of about 9.4 feet long.

Another shortcoming associated with existing sound reproduction equipment is that they do not use their housing structures and their surroundings efficiently enough so that the apparatus can be used over an optimal range of frequencies. For example, traditional horns rely solely on the physical size of the horn in order to determine the frequency range within which the apparatus may operate or function. Furthermore, existing sound reproduction equipment does not take into account its physical surroundings in order to optimize the performance of the apparatus.

Yet another shortcoming with existing sound reproduction equipment is the lack of directivity that these components provide. For example, prior art loudspeakers often generate sound in a 360° radius rather than projecting the sound in the direction the horn of the loudspeaker is pointed. This reduces the effectiveness of the loudspeaker and may limit the volume at which the loudspeaker is used due to the proximity of the sound generating instrument or person(s).

Accordingly, it has been determined that the need exists for an improved sound reproduction apparatus and method for optimally using the same which overcome the aforementioned limitations and which further provide capabilities, features and functions, not available in current devices and methods for manufacturing.

### BRIEF DESCRIPTION OF THE DRAWINGS

FIG. 1 is a block diagram of a sound reproducing apparatus embodying features of the present invention;

FIGS. 2A-B are perspective, elevational and plan views of a sound reproducing apparatus embodying features of the present invention;

FIGS. 2C-D are front and rear elevational views, respectively, of the sound reproducing apparatus of FIG. 2A;

FIGS. 2E-F are left and right side elevational views, respectively, of the sound reproducing apparatus of FIG. 2C;

FIGS. 2G-H are top and bottom views, respectively, of the sound reproducing apparatus of FIG. 2C;

FIG. 3 is a cross-sectional view of the sound reproducing apparatus of FIGS. 2A-H, as viewed along line 3-3 of FIG. 2G;

FIG. 4 is a front elevational view of another sound reproducing apparatus embodying features of the present invention shown with the front panel removed and illustrating possible dimensions of the component;

FIG. 5A is a perspective view of an alternate sound reproducing apparatus embodying features of the present invention illustrating the sound reproducing apparatus as it may be positioned in a room in accordance with the present invention;

FIG. 5B is a perspective view of the sound reproducing apparatus of FIG. 5A illustrating the sound reproducing apparatus as it may alternately be positioned in a room in accordance with the present invention;

FIG. 5C is a perspective view of the sound reproducing apparatus of FIG. 5A illustrating the sound reproducing apparatus as it may alternatively be positioned in a room in accordance with the present invention;

FIGS. 6 and 7 are Decibel vs. Frequency graphs illustrating how a sound reproducing apparatus may operate in accordance with the invention;

FIGS. 8A-B are plan and side elevational views of a sound reproducing apparatus according to the invention illustrating the sound reproducing apparatus as it may alternatively be positioned under a stage in accordance with the invention (note: the top portion of the stage is transparent in the plan view so that the sound reproducing apparatus remains visible);

FIGS. 9A-B are plan and side elevational views of sound reproducing apparatus according to the invention illustrating the sound reproducing apparatus as they may alternatively be positioned under a stage in accordance with the invention (note: the top portion of the stage is transparent in the plan view so that the sound reproducing apparatus remain visible);

FIG. 10A is a perspective view of an array of speakers as they may be configured in accordance with the invention;

FIGS. 10B-C are polar plots and a response curve, respectively, of the array of speakers of FIG. 10A;

FIG. 11A is a perspective view of an alternate array of speakers as they may be configured in accordance with the invention;

FIGS. 11B-C are polar plots and a response curve, respectively, of the array of speakers of FIG. 11A;

FIGS. 12A-B are front and side elevational views of an array of speakers as they may be configured according to the invention illustrating the effective mouth opening of the speaker horns in full space;

FIGS. 13A-B are front and side elevational views of the array of speakers from FIGS. 12A-B illustrating the effective mouth opening of the speaker horns in half space; and

FIGS. 14A-B are graphical representations of the Impedence vs. Frequency performance of sound reproducing apparatus made and used in accordance with the invention, comparing the performance of a single speaker, a two speaker array and a four speaker array.

### DETAILED DESCRIPTION OF THE INVENTION

A sound reproducing apparatus in accordance with the invention includes a body, such as a housing, a driver for reproducing a desired sound and an acoustic passageway through which the reproduced sound is output. The acoustic passageway having an internal portion, such as a horn, located within the body of the apparatus and an external portion defined by at least one of the exterior surfaces of the body and/or a boundary of the environment within which the apparatus is placed. In one form, the external portion of the acoustic path is defined by an exterior surface or surfaces of the body and a wall, floor or ceiling. In another form, the external portion of the acoustic path is defined by an exterior surface or surfaces of the body and another acoustic reproducing apparatus. In yet another form, the external portion of the acoustic path is defined by an exterior surface or surfaces of the body, by a wall, floor or ceiling, and by another acoustic reproducing apparatus.

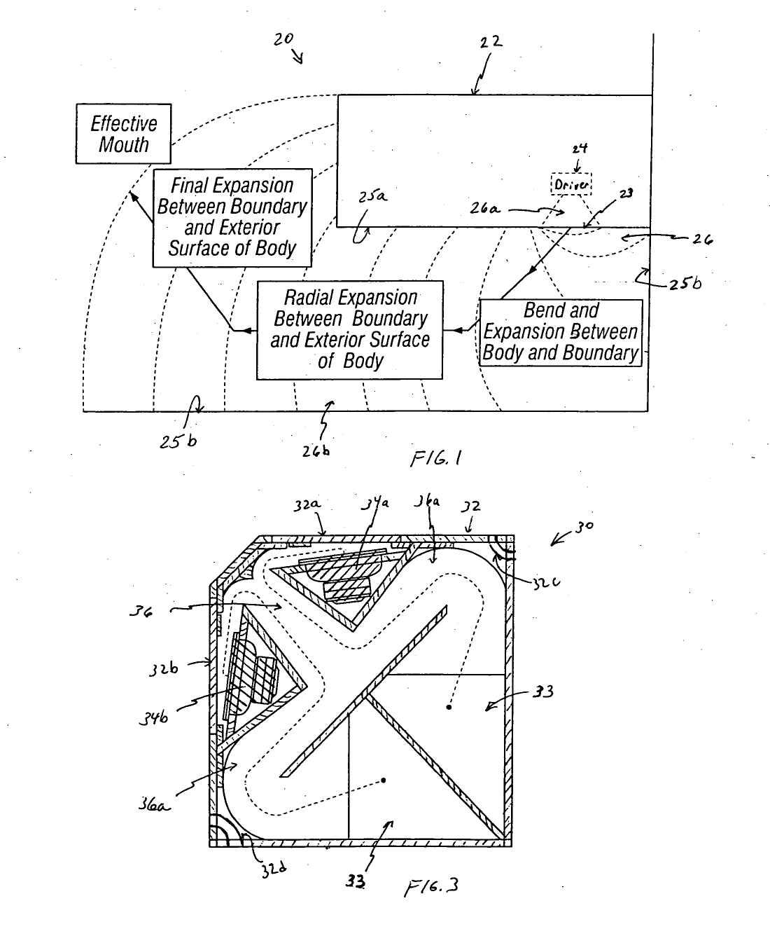

Turning first to FIG. 1, there is illustrated an acoustic reproducing apparatus 20 embodying features of the present invention. In the embodiment illustrated, the acoustic reproducing apparatus 20 has a body, such as housing 22, a driver 24, and an acoustic passageway or path 26 defined by an internal portion of the acoustic passageway 26a and an external portion of the acoustic passageway 26b. The acoustic path 26 connects the output from the driver 24 to the outside world and expands in cross section or cross sectional area as it goes from the driver on one end to the passageway mouth on the other end. The internal portion 26a expands in cross sectional area and ends in an actual or physical mouth opening 23 preferably located about a side of the body 22. The external portion 26b continues from the end of the internal portion (or actual mouth) and expands in cross sectional area and ends at an effective mouth opening. More particularly, the external portion 26b is defined by an external surface or surfaces of the body 22 and an additional boundary of the environment within which the apparatus 20 is placed, such as a ceiling, wall or floor of a room, or another surface separate from the apparatus 20 such as an exterior wall of a second acoustic reproducing apparatus.

As illustrated in FIG. 1, the reproduced acoustic is output from the driver 24 and travels through the internal portion 26a of acoustic passage 26 and out the actual mouth of the apparatus 20 at an angled expansion. The reproduced acoustic travels through the external portion of the acoustic passageway 26b between the boundary 25a defined by the external surface of the body 22 and the additional boundary 25b of the environment within which the apparatus 20 is placed and expands radially therein. Then the reproduced acoustic goes through a final expansion between another surface of the body 22 and the boundary and exits the effective mouth of the apparatus 20. Thus, the apparatus 20 is capable of using the boundary to increase the effective size of the acoustic passageway 26 and the effective mouth thereof so that the apparatus uses its housing structure and surroundings efficiently enough so that the apparatus 20 can be used over an optimal range of frequencies. Furthermore, this configuration allows lower frequencies to be reached by smaller, more affordable, pieces of equipment.

It should be understood that the exterior surfaces of the apparatus 20 form a boundary in and of themselves; thus the external portion of the acoustic passageway is defined between two boundaries external to the body 22. It should also be understood that the portions of the acoustic pathway 26 do not need to continually expand in cross sectional area, but rather expand in cross sectional area between the driver 22 and the effective mouth opening. In a preferred embodiment, however, the acoustic pathway 26 is designed to continuously expand at a rate appropriate for the desired frequency. This is done by adjusting the gap between the wall, the shape and size of the box part of the horn and the outlet size so that the passage way leading immediately away from the box outlet has the needed rate of expansion.

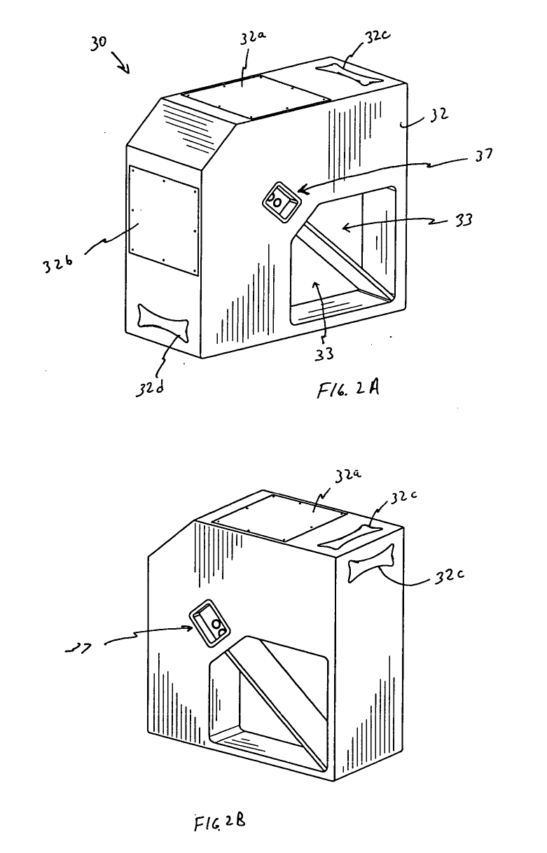

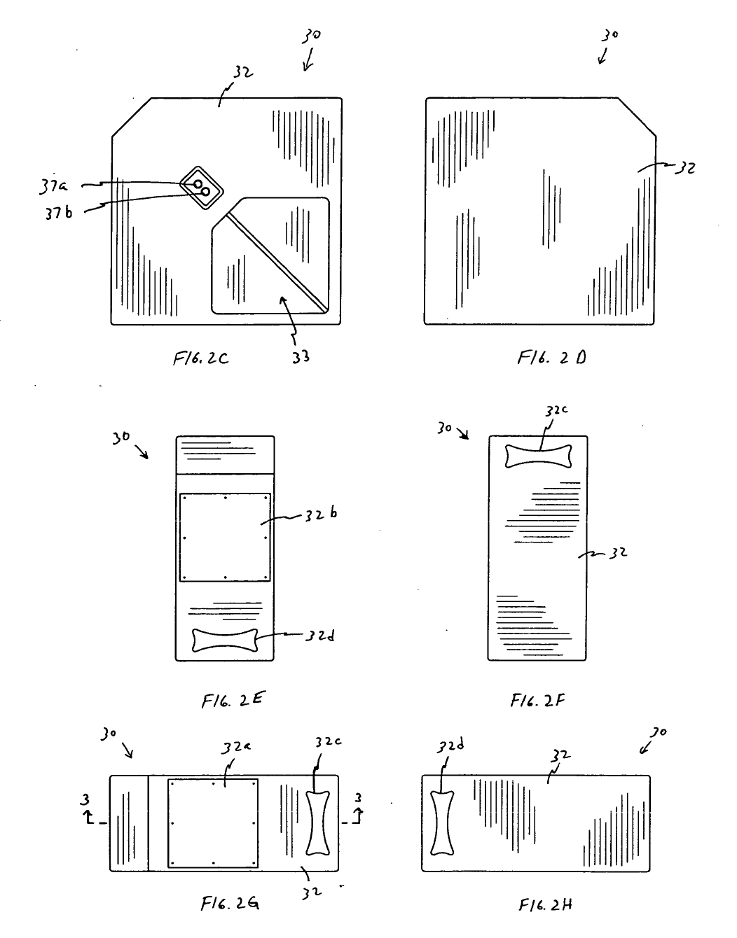

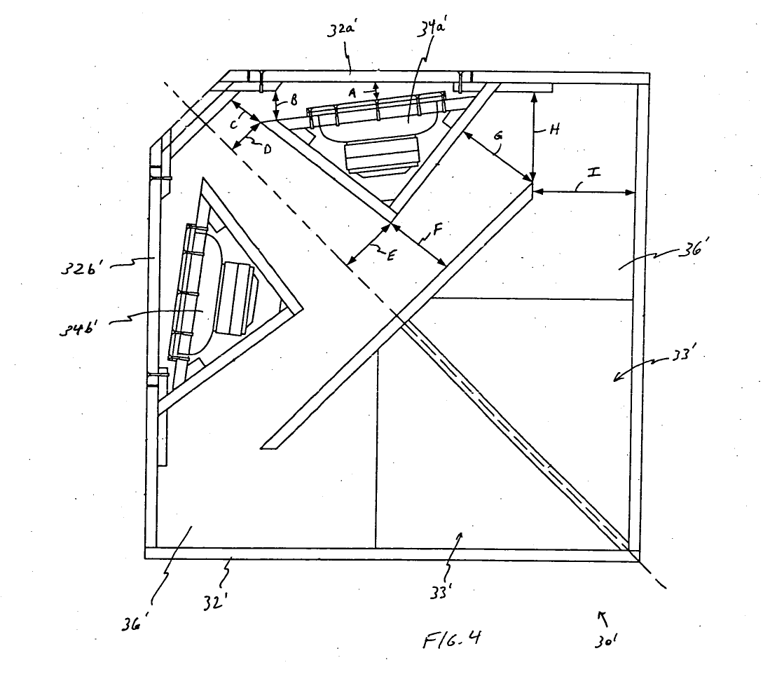

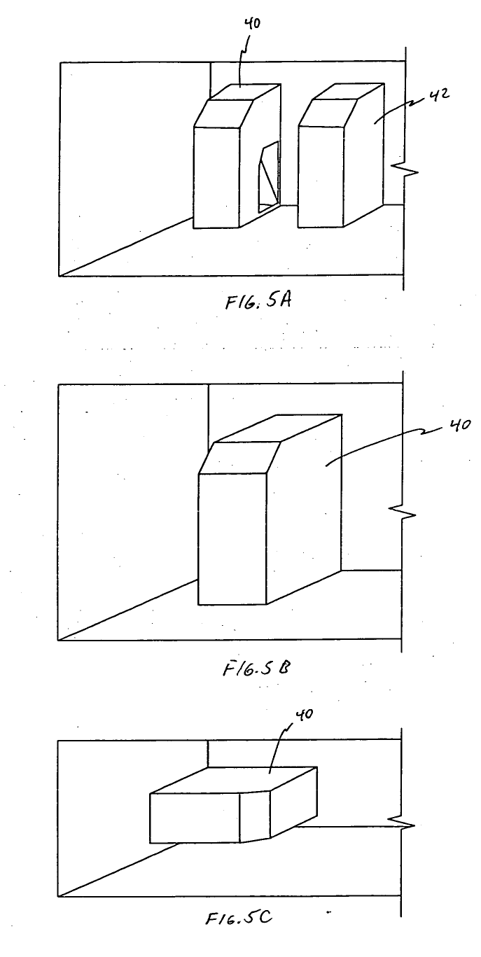

In FIGS. 2A-H and 3, there is illustrated a sound reproducing apparatus 30 embodying features of the present invention. The apparatus 30 has a polygonal shaped body 32 having first and second speakers or drivers 34a and 34b, respectively, mounted therein. The body 32 has access panels or doors 32a and 32b which provide access to drivers 34a and 34b, respectively, and defines the internal portion 36a of the acoustic passageway 36 via various internal walls thereof leading from the drivers 34a-b to the actual mouth or outlet opening 33. The drivers 34a-b are positioned within generally triangular shaped supports 32c and 32d, respectively, and are angled with respect to the outer walls of the housing 32 and/or doors 32a-b. The corners of the passageway defined by internal portion 36a are preferably rounded to assist in the acoustics of the system. However, in alternate embodiments the corners of the internal passageway 36a need not be rounded. It should also be understood that the actual internal layout of the apparatus is not as important as the length and area of the horn of the apparatus in order for the apparatus to be able to reach lower frequencies, such as 30-190 Hz. Thus, a variety of different internal layouts may be used in conjunction with the concepts disclosed herein to provide an apparatus that performs in the desired manner.

In the embodiment illustrated in FIGS. 2A-H and 3, the body 32 defines ergonomic handles 32c and 32d which a person may use to lift and carry the apparatus 30. The handles 32c-d are positioned on opposite corners of the apparatus 30 and form arcuate or curved openings that extend from one side of the body 32 to another adjacent side of the body 32. The body 32 of the apparatus 30 is preferably made from wood, such as Baltic Birch, and coated in a black catalyzed texture coat or a polyurethane such as LINE-X brand polyurethane.

The apparatus 30 also includes a terminal block 37 which has two terminals 37a and 37b that are electrically connected to mating terminals located on the drivers 34a-b. Thus, the horn 30 may be electrically connected to an audio source, such as an amplifier, to make the drivers reproduce a desired sound.

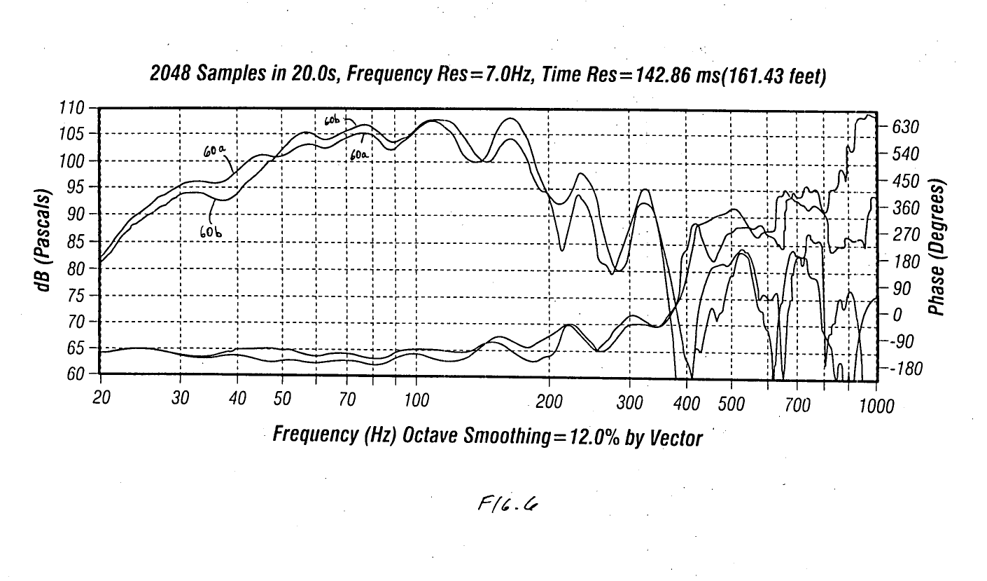

In FIG. 4, there is illustrated an alternate sound reproducing apparatus embodying features of the present invention. For convenience, features of the alternate embodiment illustrated in FIG. 4 that correspond to features already discussed with respect to the embodiments of FIGS. 2A-H and 3 are identified using the same reference numeral in combination with an apostrophe or prime notation (′) merely to distinguish one embodiment from the other, but otherwise such features are similar.

The alternate sound reproducing apparatus illustrated in FIG. 4 (hereinafter apparatus 30′) illustrates an interior portion 36a′ of acoustic passageway 36′ wherein the corners of the passage are not rounded as mentioned above. In this embodiment, the outside dimensions of the housing 32′ are approximately forty-two inches by forty-two inches by eighteen inches and the outer walls are three fourths of an inch thick. Although the housing 32′ may be made of any number of materials, the preferred embodiment uses a plywood such as Baltic Birch. The expansion of the acoustic passageway is identified by reference letters A-I, with A=2.5 inches, B=3 inches, C=3.25 inches, D=3.38 inches, E=5.25 inches, F=6 inches, G=7.88 inches, H=8 inches, I=8.13 inches. The actual mouth opening 33′ is preferably twenty-one inches by twenty-one inches (e.g., square) and is divided into two outlet openings 33a′ and 33b′ by a center mouth brace 33c′. It should be understood, however, that these dimensions are only exemplary and may vary individually or as a whole depending on the application for which the apparatus is being designed. In alternate embodiments, the apparatus 30′ may be provided without a mouth brace 33c′, however, in the embodiments illustrated, the brace 33c′ is provided to strengthen and/or reinforce the assembled apparatus.

The reproduced acoustics output by the drivers travel through the acoustic passageway (as illustrated by the broken lines 35a-b in FIG. 3) and exit the internal portion of the acoustic passageway out through the actual mouth defined thereby. The reproduced acoustic output then travels through the external portion of the acoustic passage which is defined by the boundaries of the system external to the body of the sound reproducing apparatus. As mentioned above, by using the boundaries in this way, the apparatus operates as if it has a larger acoustic passageway or horn and a larger horn mouth than it actually does. Thus, a more powerful and efficient acoustic reproducing apparatus may be provided in a smaller package and with less materials and associated costs.

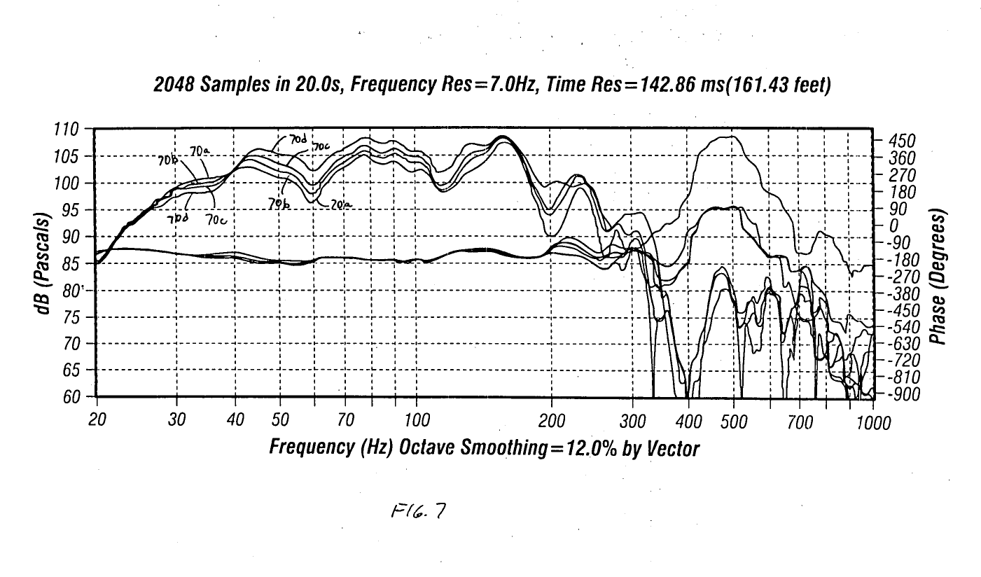

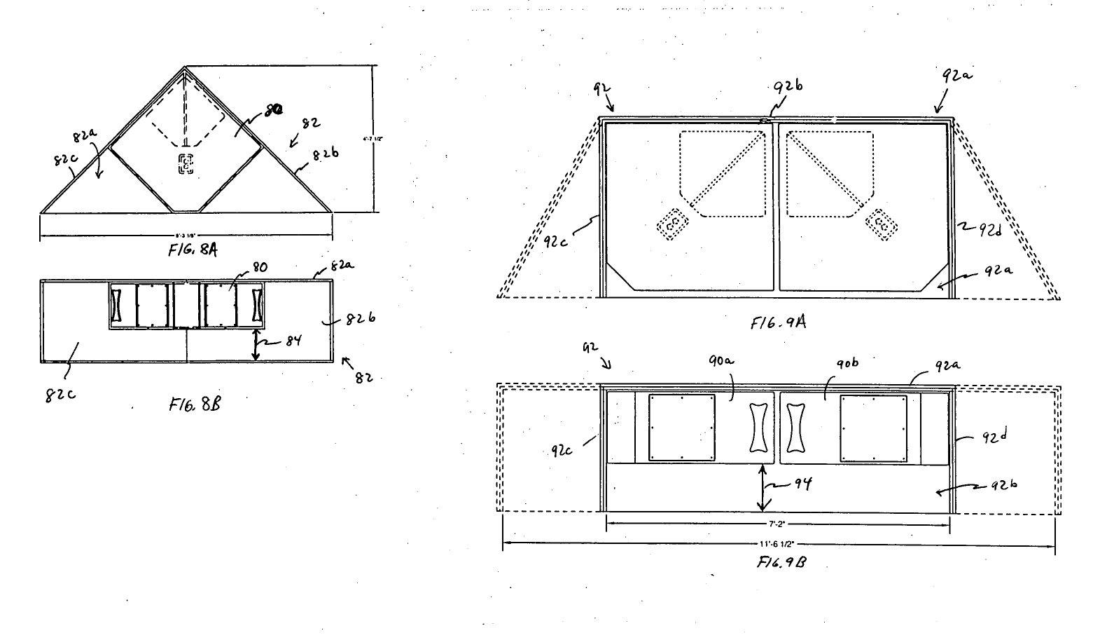

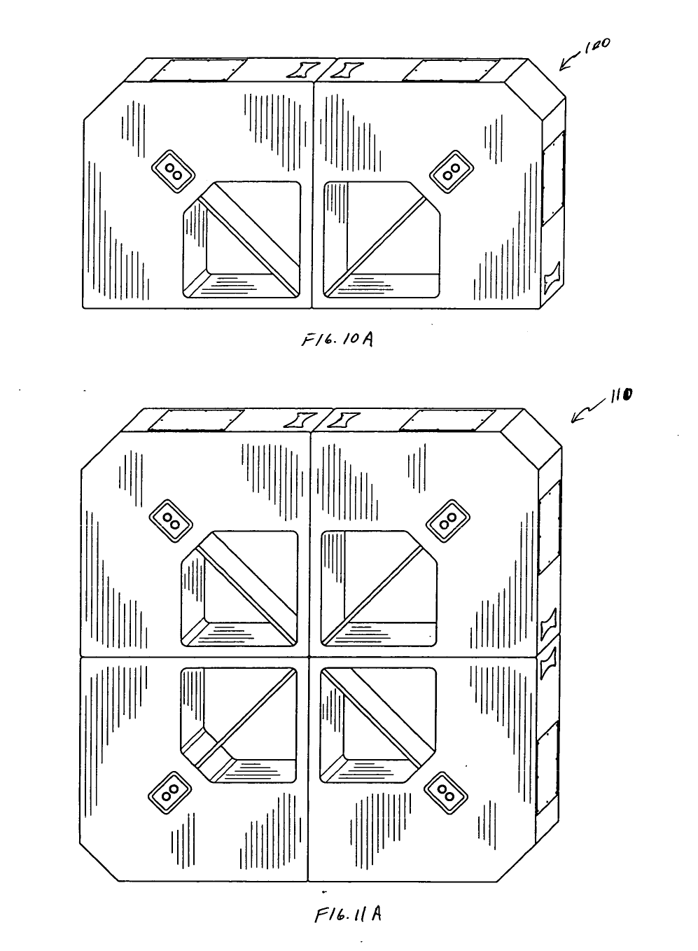

An apparatus embodying the present invention may be positioned in a variety of ways in order to take advantage of the concepts disclosed herein, as illustrated in FIGS. 5A-C. For example, an acoustical reproducing apparatus 40 is positioned facing another acoustical reproducing apparatus 42 in FIG. 5A. The reproduced acoustical output travels through the internal portion of the acoustic passageways within the apparatus 40 and 42 and use the exterior surfaces of the apparatus 40 and 42, as well as the floor and wall to form the external portion of the acoustic passageway. By positioning the actual mouth openings 40a and 42a of the apparatus 40 and 42, respectively, in the lower corner, near the intersection of the wall and floor, the external portion of the acoustical passageway, which is defined by the boundaries created by the floor, wall and exterior surfaces of the apparatus 40 and 42, is allowed to continuously expand in cross sectional area at rate desirable for producing lower frequencies (e.g., 30-190 Hz).

In an alternate configuration, the apparatus 40 may be positioned with the actual. mouth opening facing a corner of a room as illustrated in FIG. 5B in order to use the floor, walls, and exterior surface of the apparatus 40 to provide the external portion of the acoustical passageway. Again, by placing the actual opening in the lower corner, near the intersection of the wall and floor, the external portion of the acoustical passageway is allowed to continuously expand in cross sectional area at the desired rate.

In yet other configurations, the apparatus 40 may be positioned with the actual opening facing the floor of a room as illustrated in FIG. 5C in order to use the floor, surrounding walls and exterior of the apparatus to form the external portion of the acoustic passageway. The opening of the apparatus 40 is placed in the corner to allow the external portion of the acoustical passageway to continually expand in cross sectional area to produce a larger and more effective mouth opening. In this configuration, the mouth of the horn need only be ⅛th the size of the mouth of a horn suspended in full space (e.g., suspended in air with no immediate boundaries). Using the dimensions provided above and mounting the apparatus in the manner illustrated in FIG. 5C, the exterior portion of the horn passageway is about seventy-five inches long.

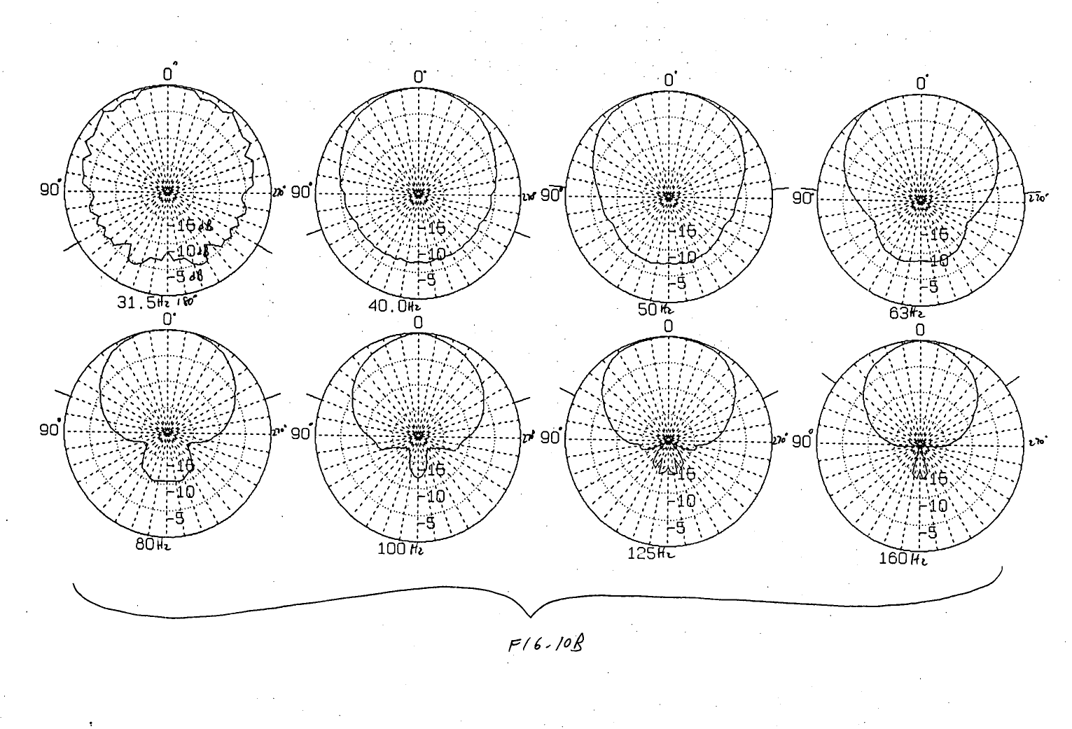

In FIGS. 6 and 7, frequency vs. decibel graphs are illustrated showing how a sound reproducing apparatus made and used in accordance with the invention may operate. For example, in FIG. 6, response curves 60a and 60b represent the loudness per frequency for a single sound reproducing apparatus in accordance with the invention when the apparatus is positioned in a room approximately mid-wall. The first response curve 60a illustrates the performance of the apparatus when it is positioned 45° to the wall, and the second response curve 60b illustrates the performance of the apparatus when it is positioned 90° to the wall. As illustrated in this graph, the apparatus produces more power (or watts) from 30-49 Hz when it is positioned 45° to the wall, and more power (or watts) from 49-100 Hz when it is positioned 90° to the wall.

In FIG. 7, response curves 70a, 70b, 70c and 70d represent the performance of the apparatus when positioned in a corner as illustrated in FIG. 5C. The differences in the curves 70a-d is due to differences in the size of the gap between the apparatus and the surrounding wall and floor boundaries. For example, curve 70a illustrates the performance of the apparatus when the gap is approximately ten inches, curve 70b illustrates the performance of the apparatus when the gap is approximately twelve inches, curve 70c illustrates the performance of the apparatus when the gap is approximately fourteen inches, and curve 70d illustrates the performance of the apparatus when the gap is approximately ten inches. As illustrated in this graph, the apparatus works best between 30-38 Hz when the gap is smaller (e.g., approximately ten inches), and works better between 44-100 Hz when the gap is larger (e.g., approximately eighteen inches).

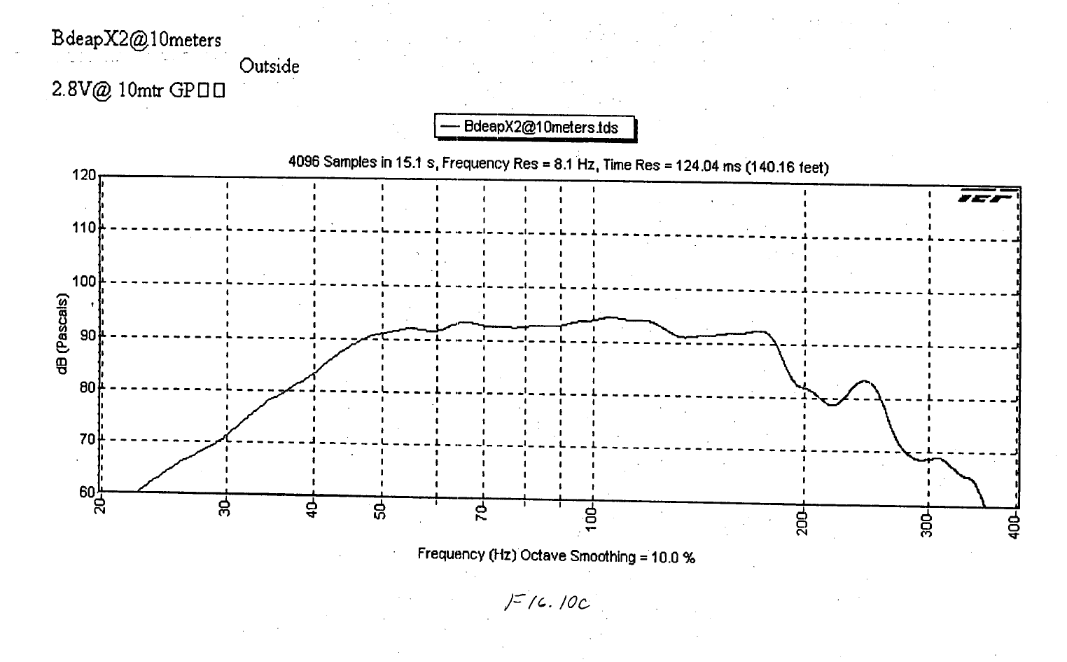

In FIGS. 8A-B, a sound reproducing apparatus in accordance with the invention is illustrated showing the apparatus 80 as it may alternatively be positioned under a stage 82 in accordance with the invention. The top portion 82a of the stage 82 is transparent in FIG. 8A so that the apparatus 80 remains visible for purposes of discussion. In this configuration, the apparatus is positioned in a corner defined by the stage walls 82a, 82b and 82c. The actual outlet or mouth of apparatus 80 faces the floor and the apparatus 80 is preferably positioned sufficiently above the floor to form an acoustic pathway or gap between the exterior surfaces of the apparatus 80 and the floor and walls of the stage 82. As discussed above, this will effectively lengthen and increase the size of the horn of the apparatus 80.

The apparatus 80 will be most effective with a pathway or gap clearance 84 of about ten to twenty inches. The gap can be made larger or smaller if desired, however, such changes may limit the effectiveness of the apparatus 80. For example, the apparatus 80 will function with a six inch gap, but such a change will attenuate the apparatus response at frequencies above 100 Hz and will create more pressure in the cavity defined by the stage and exterior surfaces of the apparatus 80. The graph of FIG. 7 may be consulted to assist in selecting the best gap clearance for a particular application. Alternatively, the sound reproducing apparatus discussed herein may be provided in a kit format with an instruction manual explaining how the apparatus is to be positioned in an environment to optimize the performance thereof.

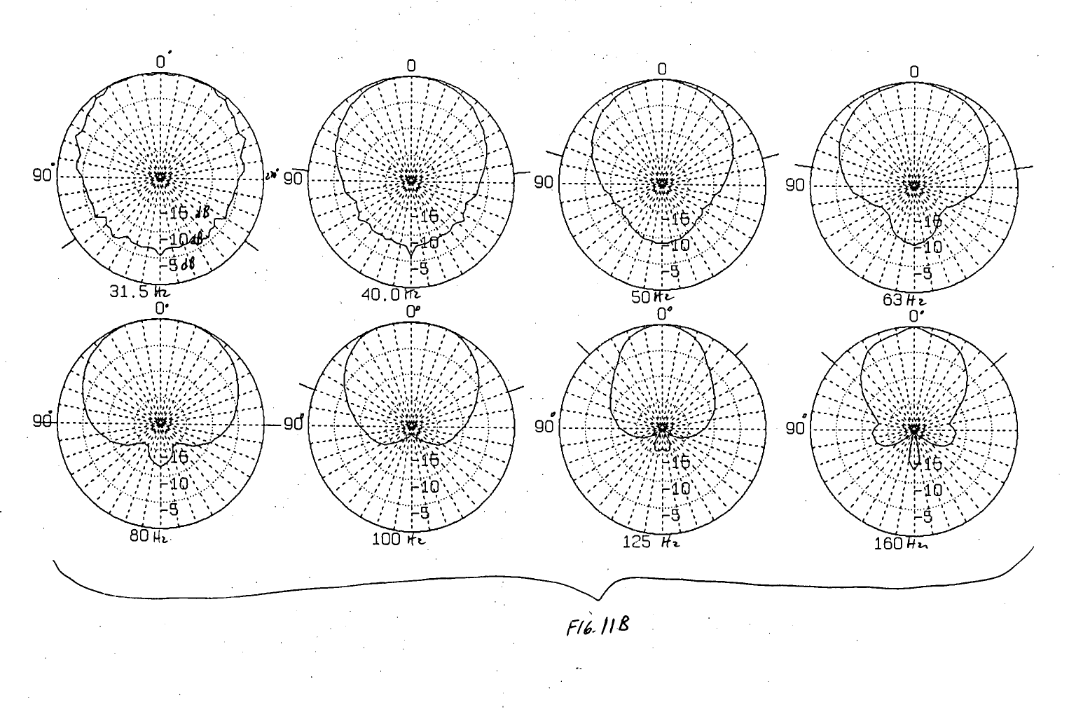

Alternatively, a sound reproducing apparatus in accordance with the invention may be configured with two speakers 90a and 90b positioned under a stage 92 as illustrated in FIGS. 9A-B. For convenience, the top portion of the stage 92a is transparent in FIG. 9A so that the apparatus 90a and 90b remain visible. In this configuration, the apparatus 90a-b are positioned with their actual mouth openings next to one another and facing the floor. The floor, walls 92b, 92c and 92d, and exterior surfaces of the apparatus 90a-b form boundaries which define the exterior portion of the acoustic path and allow the apparatus 90a-b with much larger horns and horn openings. To further improve the performance of the apparatus 90a-b, the walls 92b, 92c and 92d of stage 92 may be expanded or angled as illustrated in broken lines in FIGS. 9A-B in order to increase the rate of expansion of the cross sectional area of the acoustic pathway, if desired. The broken lines illustrate a 30° widening as an example. In addition, and as mentioned above, the apparatus 90a-b will be most effective with a pathway or gap clearance 94 of about ten to twenty inches.

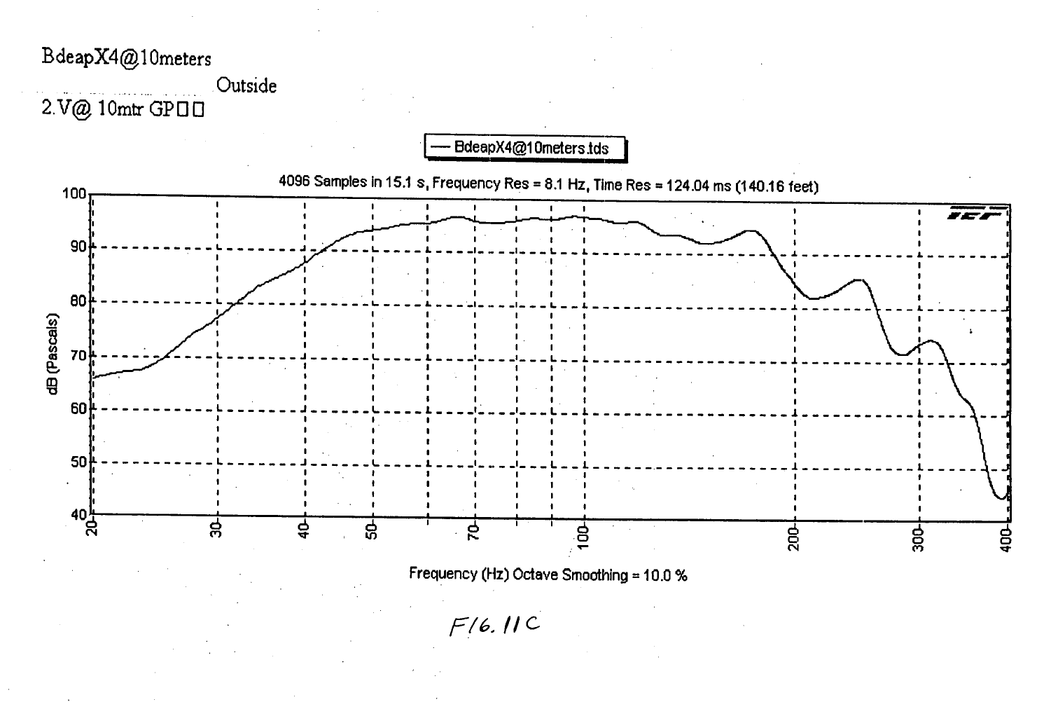

FIG. 10A is a perspective view of an array of speakers 100 as they may be configured in accordance with the invention and similar to the configuration shown in FIGS. 9A-B. FIGS. 10B-C illustrate polar plots and a response curve, respectively, for the speaker array 100 of FIG. 10A. More particularly, FIG. 10B illustrates the acoustical sound power level of the speaker array 100 at 31.5 Hz, 40 Hz, 50 Hz, 63 Hz, 80 Hz, 100 Hz, 125 Hz and 160 Hz. To best understand these plots, the reader should picture the array of speakers 100 placed in the center of each plot with the actual mouth openings facing the position identified as 0° (the 0° point is referred to as “on axis”). The acoustic line or plot of a typical prior art speaker would appear as an almost perfect sphere. Meaning that the speaker would be almost as loud (if not as loud) from behind (e.g., the 90° position) as it would be from head on (e.g., on axis). The sound reproducing apparatus of the present invention, however, is capable of directing the sound from the speakers in a much more focused manner as illustrated by the plots of FIG. 10B. By doing so, the speaker array 100 is capable of utilizing the directivity to provide more power or watts per meter than any available speaker to date.

Each polar plot of FIG. 10B has been normalized to zero. Thus, the decibel level of the speaker array 100 at 0° may be found by looking at the response curve illustrated in FIG. 10C. For example, at 31.5 Hz, the speaker array 100 is capable of generating approximately 72 dB, which is the normalized decibel level at 0° in the first polar plot of FIG. 10B. Similarly, at 40 Hz, the speaker array 100 is capable of generating approximately 83 dB, which is the normalized decibel level at 0° in the second polar plot of FIG. 10B. However, it should be understood that this data was taken at 10 meters rather than the usual 1 meter. Therefore, to determine the actual power of the speaker array 100, 20 dB should be added to the figure taken from the graph of FIG. 10C in order to calculate the actual watts/meter. Thus, at 31.5 Hz, the speaker array 100 is capable of generating approximately 92 dB. Similarly, at 40 Hz, the speaker array 100 is capable of generating approximately 103 dB.

In looking at FIG. 10B, the average decibel reading at the mid-band frequencies is approximately 93 dB. After adding 20 dB to get a proper reading per meter, the speaker array 100 will be understood to generate approximately 113 dB on average. To put this in perspective, one must realize that a one hundred percent (100%) efficient speaker would only be able to produce 112 dB and that prior art speakers do not operate at one hundred percent (100%) efficiency and are typically only fifty percent (50%) efficient and able to produce about 106 dB. The dramatic improvement of the speaker array 100 over the prior art is due, at least in part, to the use of boundaries to create an effectively larger horn and horn mouth and to the improved directivity of the apparatus which results from its design as illustrated in FIG. 10B. By focusing the performance of the speaker array toward the intended audience, the apparatus is capable of generating a louder, more powerful output. As can been seen in FIG. 10B, the directivity of the speaker array 100 improves as the frequency increases and, as expected, the speaker is capable of producing more decibels as the frequency increases from 30-60 Hz and beyond.

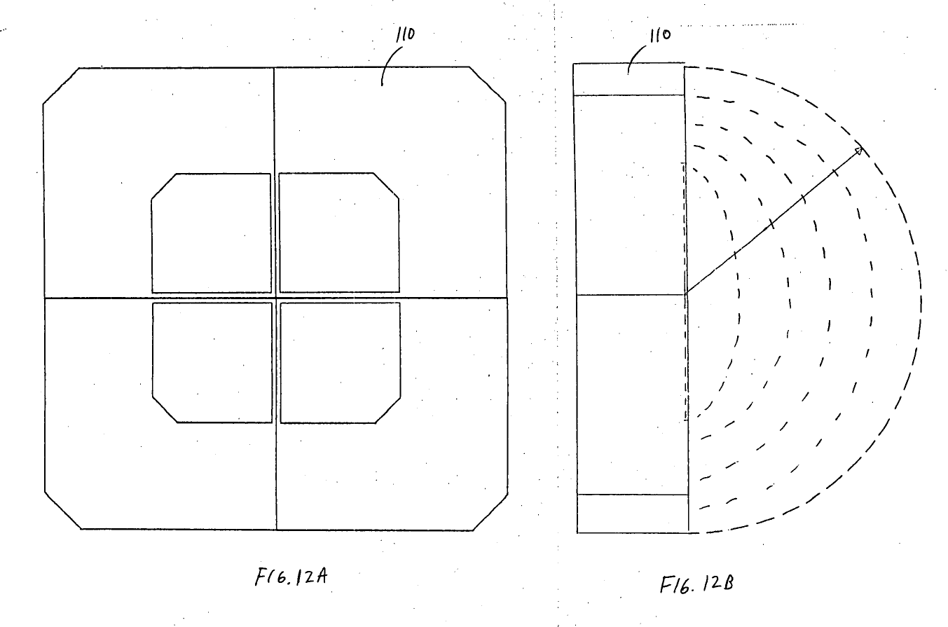

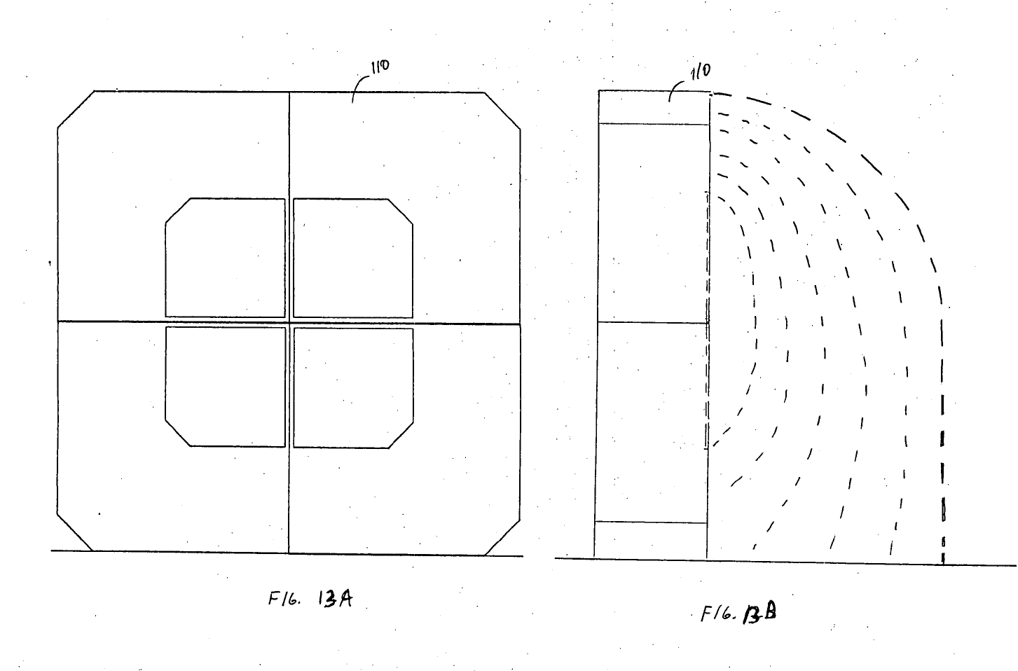

FIG. 11A is a perspective view of another array of speakers 110 as they may be configured in accordance with the invention. FIGS. 11B-C provide polar plots and a response curve, respectively, for the speaker array 100 of FIG. 11A, similar to those discussed above with respect to speaker array 100. For example, the polar plots of FIG. 11B illustrate the acoustical sound power level of the speaker array 110 at 31.5 Hz, 40 Hz, 50 Hz, 63 Hz, 80 Hz, 100 Hz, 125 Hz and 160 Hz. As illustrated in FIG. 11C, at 31.5 Hz, the speaker array 110 is capable of producing approximately 79 dB at 10 m, which translates into 99 dB at 1 m (e.g., 79 dB+20 dB). The average decibel reading at the mid-band frequencies for speaker array 110 is approximately 97 dB at 10 m, or 117 dB at 1 m. Thus, the configuration of speaker array 110 is capable of producing ten times more sound output per watt/m than existing speakers. Furthermore, as illustrated in the polar plots of FIG. 11B, the speaker array 110 is capable of producing ten to one hundred times (10×-100×) more energy in front of the apparatus than behind it. Thus, the use of boundaries to create an effectively larger horn and horn mouth and the resulting improved directivity of the apparatus make the speaker array 110 vastly out perform traditional speaker systems.

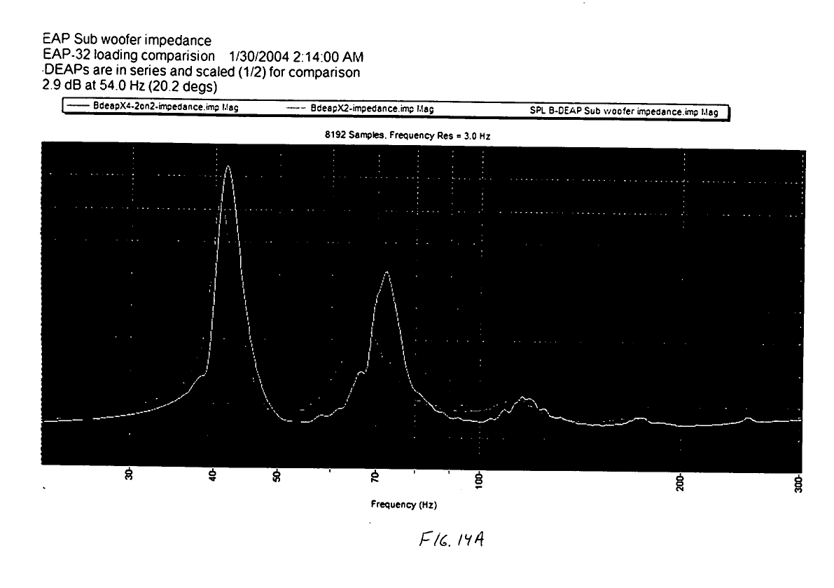

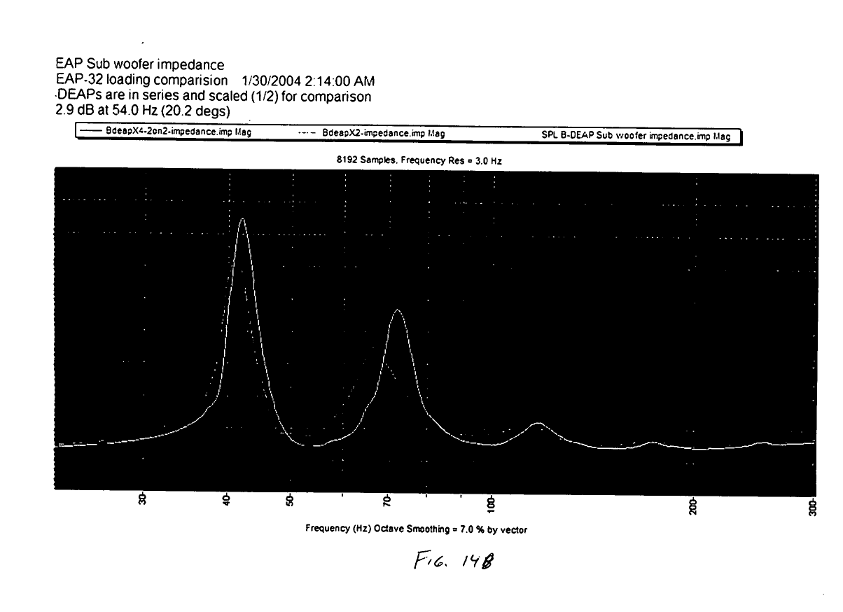

FIGS. 12A-B illustrate the speaker array 110 in full space (e.g., hanging in air with no immediate boundaries other than the exterior surfaces of the speaker bodies) and illustrate how the exterior surfaces of the speaker bodies serve to increase the effective horn length and horn opening for the apparatus. More particularly, the exterior surfaces of the speakers adjacent the actual speaker outlets, increase the horn angle to 180°. Thus, the size of the outlets, together with the boundaries created by the exterior surfaces of the speaker bodies, allow the apparatus to have an acoustic rate of expansion that is slow enough to act like a large horn with a big horn mouth at low frequencies. By reducing the size of the outlet or actual mouth openings by fifty percent (50%), the rate of expansion would be too rapid to effectively use the apparatus at low frequencies. Similarly, FIGS. 13A-B illustrate the speaker array 110 in half space (e.g., resting on the ground) and illustrate how the exterior surfaces of the speaker bodies and the ground serve to increase the effective horn length and horn opening and allow the horn to maintain an expanding cross sectional area.

The above discussion should help explain that, while a quarter wavelength long horn functions at a quarter wavelength, the actual efficient range of operation does not begin until the horn path length is approaching one half wavelength. This is because at its shortest length (e.g., a quarter wavelength), there is a velocity maximum at the mouth end and a velocity minimum at the driver end. This minimum also means the motion and impedance is at a minimum at this point as well. The one half wavelength horn on the other hand has a velocity maximum at both ends (with a minimum somewhere near the center of the horn) and so the driver motion is greater as well as the impedance. This is needed as efficiency Is the ratio of the radiated power compared to that lost due to power losses (I² losses), etc. For a fifty percent (50%) efficient horn, the load impedance is resistive and approximately two times (2×) the Rdc of the driver. Thus, one can see if the input power is lost due to power losses (I²R losses) and the other half is the reflected radiation impedance of the system. To further complicate things, having a large enough mouth is important in order to have a “flat” response. A mouth that is too small will produce ripples even where the driver and other components are operating fine. As such, the mouth of the horn needs to be about one wavelength in circumference at the low cut off frequency or larger. In other words, the apparatus discussed herein allows the majority of the cubic space that the big end of the horn requires to be made up from the shape and size of the passage way outside the enclosure. This allows for a great reduction in the size of the enclosure and an increase of the actual horn path length to approximately one half wavelength.

Thus, the boundaries of the apparatus may be used effectively to reduce the overall size the apparatus needs to be in order to work properly. For example, each time the radiation space is cut in half (e.g., from full space (hanging in air) to half space (resting on ground), half space to quarter space (on ground near wall), quarter space to one-eighth space (in a corner), etc.) the needed horn mouth area is halved. In addition, the sound reproducing apparatus will have more directivity and be capable of producing more decibels than existing speakers. FIGS. 14A-B provide a graphical comparison of the various apparatus configurations discussed above and illustrated advantages to each.

It should be understood that in other embodiments, the acoustic reproducing apparatus may have additional drivers which are each capable of reproducing different frequencies or frequency ranges. For example, in one form the apparatus disclosed herein may include a horn with frequency division such as that disclosed in U.S. Pat. No. 6,411,718, issued Jun. 25, 2002 to Danley et al., and published U.S. Patent Application Publication No. 2002/0106097, published Aug. 8, 2002, which are hereby incorporated herein by reference in their entirety. Thus, it should be understood that the concepts and methods disclosed herein may be applied to any acoustic reproducing apparatus and not simply those specific embodiments discussed herein.

Thus, in accordance with the present invention, n acoustic reproducing apparatus and method of optimizing boundary use therewith are provided that fully satisfy the objects, aims, and advantages set forth above. While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims.

1. An apparatus for reproducing sound comprising:
a body;
a driver for reproducing a desired sound; and
an acoustic passageway having first and second passageway portions, the first passageway portion being defined by a portion of the body and the second passageway portion being defined by an exterior boundary.

2. An apparatus according to claim 1 wherein the first acoustic passageway portion comprises a horn located within the body of the apparatus.

3. An apparatus according to claim 1 wherein the body has exterior surfaces thereof and the boundary defining the second acoustic passageway portion comprises at least one of the exterior surfaces of the body or a boundary of the environment within which the apparatus is placed.

4. An apparatus according to claim 3 wherein the boundary of the environment is a wall, floor or ceiling.

5. An apparatus according to claim 1 wherein the body defines at least one handle for lifting or carrying the apparatus.

6. An apparatus according to claim 5 wherein the body is generally rectangular in shape and has a plurality of external surfaces and the handle has a first opening located on one side of the body and a second opening located on a second side of the body, the openings being connected to form a passage through the body of the apparatus.

7. An apparatus according to claim 6 wherein the first and second openings are located adjacent a corner of the body and form the corner of the body into a post to be grasped when lifting or carrying the apparatus.

8. An apparatus for reproducing sound comprising:
a first speaker having a body defining a horn and a horn opening located in a corner thereof; and
a second speaker having a body defining a horn and a horn opening located in a corner thereof, the first and second speakers being positioned adjacent one another and having both horn openings generally adjacent one another to form a side-by-side array of speakers.

9. An apparatus according to claim 8 further comprising a second side-by-side array of speakers, the first and second arrays being positioned adjacent one another and having the horn openings located generally adjacent one another to form a four speaker array.

10. A method for reproducing sound with a speaker, the method comprising:
providing a body having an acoustical passageway that defines a first portion of a horn; and
using boundaries external to the body to define a second portion of the horn to effectively increase the size of the horn.

11. A method according to claim 10 wherein the body has exterior surfaces thereof and the step of using boundaries external to the body comprises:
using at least one of the exterior surfaces of the body or a boundary of the environment within which the apparatus is placed to define the second portion of the horn.

12. An method according to claim 10 wherein using a boundary of the environment within which the apparatus is placed comprises using a wall, floor or ceiling to define at least a portion of the second portion of the horn.

13. A kit for reproducing sound comprising:
a body having a driver for reproducing a desired sound and an acoustic passageway having first and second passageway portions, the first passageway portion being defined by a portion of the body and the second passageway portion being defined by an exterior boundary; and
instructions for positioning the body in a manner that uses the exterior boundary to define the second passageway portion of the acoustic passageway.

14. A apparatus for reproducing sound comprising:
a body having a driver for reproducing sound, the body being generally rectangular in shape and having a plurality of external surfaces; and
a handle having a first opening located on one side of the body and a second opening located on a second side of the body, the openings being connected to form a passage through the body of the apparatus.

15. An apparatus according to claim 14 wherein the first and second openings are located adjacent a corner of the body and form the corner of the body into a post to be grasped when lifting or carrying the apparatus.
